(19) United States
(12) Patent Application Publication
(10) Pub. No.: US 2025/0116745 A1
(43) Pub. Date: Apr. 10, 2025

(54) SUBSTRATE AND A METHOD FOR TESTING A MAGNETORESISTIVE SENSOR

(71) Applicant: Infineon Technologies AG, Neubiberg (DE)

(72) Inventors: Wolfgang RABERG, Sauerlach (DE); Milan AGRAWAL, Muenchen (DE)

(21) Appl. No.: 18/901,624

(22) Filed: Sep. 30, 2024

(30) Foreign Application Priority Data
Oct. 4, 2023 (DE) 102023126972.0

(51) Int. Cl. G01R 35/00; G01R 33/09

(52) U.S. Cl. CPC G01R 35/00; G01R 33/093

(57) ABSTRACT

The implementation proposes a substrate and a method for heating a magnetoresistive sensor. The substrate includes a wire-on-chip (WoC) layer. The WoC layer has one or more conductive WoC wires for generating a magnetic field, the one or more conductive WoC wires being integrated in a chip plane. The substrate further includes a heating layer. The heating layer has one or more conductive heating wires for increasing a temperature of the substrate.

### CROSS-REFERENCE TO RELATED APPLICATION

This application claims priority to Germany Patent Application No. 102023126972.0 filed on Oct. 4, 2023, the content of which is incorporated by reference herein in its entirety.

### TECHNICAL FIELD

The present disclosure relates to magnetoresistive sensors and to the investigation of the functionality of magnetoresistive sensors at different temperatures.

### BACKGROUND

xMR sensors, also called magnetoresistive sensors, are a type of electronic sensor that detects and measures magnetic fields. xMR sensors specifically use the magnetoresistive effect, a change in the electrical resistance of a material when it is exposed to a magnetic field. xMR sensors are increasingly being used in a multiplicity of applications, from consumer and industrial applications to highly demanding and critical automotive and aerospace applications.

To ensure full functionality, xMR sensors should have their properties tested over a wide temperature range. One way to do this is to perform electrical and magnetic tests at wafer level at different temperatures. For this purpose, all wafers in a batch are subjected to a first test in which the substrate holder is set to a first temperature. The test also comprises an initial test insertion, including inserting a probe needle or a test contact at a specific location on the wafer in order to perform the electrical and magnetic tests. To establish electrical contact with the sensors, probe needles or test contacts are precisely aligned and inserted into dedicated test pads or bond pads on the wafer surface. The insertion process requires a high level of precision and control to ensure that the probes are in correct contact with the test pads and thus enable reliable tests.

The test may be continued by setting the substrate holder to a second temperature for a second test insertion. Depending on the accuracy required, a third test at a third temperature may be necessary. This entire process is lengthy and complicated and also requires special care in terms of reliable data processing so that the measurement result of the various test insertions is able to be assigned correctly.

There is therefore a need for a structure and a test method that enable more efficient testing of the properties of magnetoresistive sensors at different temperatures.

### SUMMARY

This need is met by a substrate and a method as claimed in the independent claims. Further aspects and refinements are described in the dependent claims, the following description, and the figures.

A first aspect of the present disclosure relates to a substrate. The substrate includes a wire-on-chip (WoC) layer. The WoC layer has one or more conductive WoC wires for generating a magnetic field, the one or more conductive WoC wires being integrated in a chip plane. The substrate further includes a heating layer. The heating layer has one or more conductive heating wires for increasing a temperature of the substrate. Compared to multiple test insertions for testing purposes, in which a probe needle has to be inserted at a precisely defined location (for example on a wafer), the substrate disclosed herein may require only a single insertion. Temperature changes are able to be achieved in a stable manner, originating from the substrate itself and leaving the test equipment undisturbed.

A second aspect of the present disclosure relates to a method. The method includes placing a substrate and a magnetoresistive sensor in a temperature-controlled environment. The substrate has a wire-on-chip (WoC) layer, including one or more conductive WoC wires integrated in a chip plane. The substrate further has a heating layer, including one or more conductive heating wires. The magnetoresistive sensor is in direct contact with the heating layer. The method further includes setting a temperature of the substrate to a first temperature in accordance with the temperature-controlled environment. The method further includes providing a first electric current for the heating wires in order to increase the temperature of the substrate to a second temperature and providing a second electric current for the WoC wires in order to generate a magnetic field. The method further includes measuring and recording a resistance or an impedance of the magnetoresistive sensor at the first temperature and at the second temperature of the substrate. This makes it possible to efficiently ensure that the xMR sensor 132 is able to operate stably within a predefined temperature range at a large number of temperatures and with rapid temperature changes.

### BRIEF DESCRIPTION OF THE DRAWINGS

Some examples of devices and/or methods are explained in more detail below merely by way of example with reference to the accompanying figures. In the figures:

FIG. 1 schematically shows a first example of a substrate that is in direct contact with an xMR layer comprising a magnetoresistive sensor;

FIG. 2A schematically shows two example elements of a magnetoresistive sensor, each having a pinned layer and a free layer;

FIG. 2B schematically shows one example of an xMR sensor having four elements in the form of a Wheatstone measuring bridge;

FIG. 3 schematically shows one example of a substrate having an xMR layer comprising a magnetoresistive sensor;

FIG. 4 schematically shows conductive wires of an example heating layer;

FIG. 5 shows a graph of a distributed temperature change of an example heating layer;

FIG. 6 shows a graph of a temperature change and resistance change of conductive polycrystalline silicon wires, as a function of a provided current for one of the heating layers described herein; and

FIG. 7 shows a flowchart of an example method for investigating the functionality of a magnetoresistive sensor at different temperatures.

### DESCRIPTION

Some examples are now described in more detail with reference to the accompanying figures. Further possible examples are however not restricted to the features of these implementations that are described in detail. These may contain modifications of the features and equivalents and alternatives to the features. The terminology used herein to describe particular examples is also not intended to be restrictive for further possible examples.

The same or similar reference signs relate, throughout the description of the figures, to the same or similar elements or features, which may each be implemented identically or else in a modified form, while providing the same or a similar function. In the figures, the thicknesses of lines, layers and/or regions may also be exaggerated for clarification.

When two elements A and B are combined using an “or”, this is to be understood as meaning that all possible combinations are disclosed, that is to say only A, only B, and also A and B, unless expressly defined otherwise in the individual case. “At least one of A and B” or “A and/or B” may be used as alternative wording for the same combinations. This applies equivalently to combinations of more than two elements.

If a singular form, for example “a, an” and “the”, is used, and the use of only a single element is neither explicitly nor implicitly defined as mandatory, other examples may also use multiple elements to implement the same function. When a function is described in the following as being implemented using multiple elements, further examples may implement the same function using a single element or a single processing entity. Furthermore, it will be understood that the terms “comprises”, “comprising”, “has” and/or “having” when used describe the presence of the indicated features, whole numbers, steps, operations, processes, elements, components and/or a group thereof, but do not thereby exclude the presence or the addition of one or more further features, whole numbers, steps, operations, processes, elements, components and/or a group thereof.

Magnetoresistive sensors (that is to say xMR sensors) are generally configured such that they use the magnetoresistive effect to detect and measure surrounding magnetic fields. This is done by changing the electrical resistance of a material, which change may be proportional to the magnetic field strength. However, the measured value of the sensor may change depending on the temperature, which constitutes an undesirable behavior. To test the properties and functionality of the xMR sensor, a stable, predefined magnetic field may be generated while the xMR sensor is connected via an electrical line. It is thereby possible to measure a change in resistance or impedance based on the predefined magnetic field. In addition, provision may be made for a mechanism for changing the temperature of the xMR sensor during such measurements.

Conventional test methods may be tedious and time-consuming, and generally require multiple insertion of the wafer and probe needle, in each case after a substrate holder has been set to a higher temperature. A new test method could be possible for a specially configured substrate. A previously defined magnetic field may be generated with the aid of a first set of conductive wires within a first layer of a substrate in direct proximity to the xMR sensor while its electrical resistance or impedance is being tested. Furthermore, a predefined temperature change of the xMR sensor may be made possible with the aid of a second set of conductive wires within a second layer of the substrate, which may likewise be positioned in direct proximity to the xMR sensor.

This makes it possible to achieve temperature changes in a stable form. With direct contact between the second layer of the substrate and the xMR sensor, the temperature changes may originate from the substrate itself and leave the test equipment undisturbed. Multiple magnetic fields may be generated and different temperatures may be provided, all in the same test insertion. The substrate 100 thus enables a new and more efficient form of testing an xMR sensor.

The electrical resistance during testing refers to the resistance with which a material opposes the flow of electric current, measured in ohms. To measure resistance, the broader term impedance may also be used, this likewise being measured in ohms. Impedance may comprise resistance and reactance, with coils and capacitors also occurring (for example in circuits). A frequency dependence and complex variables, with absolute values and phases, should also be considered here.

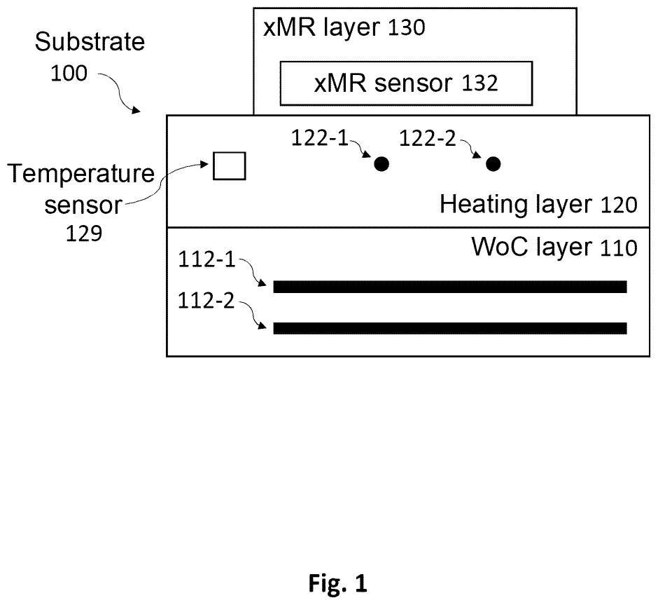

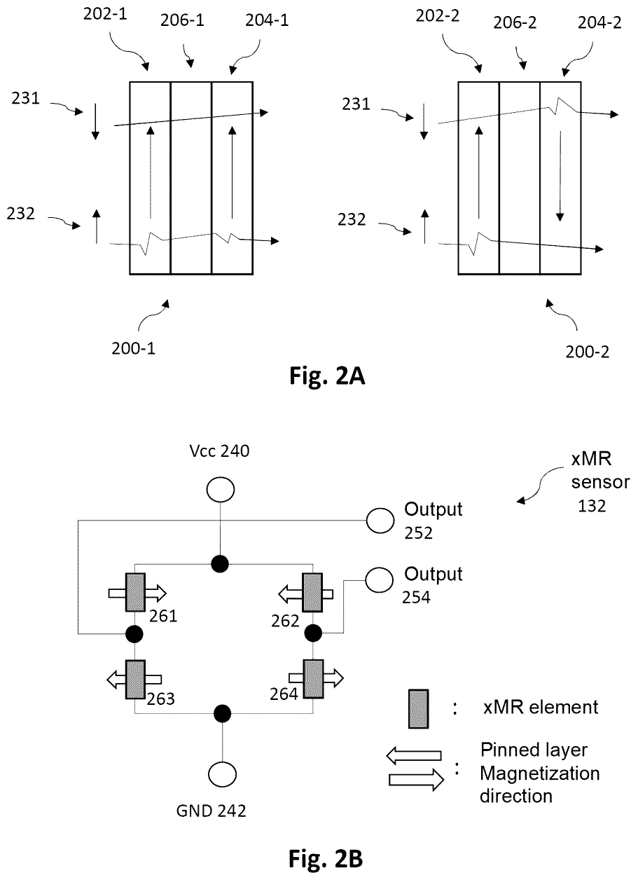

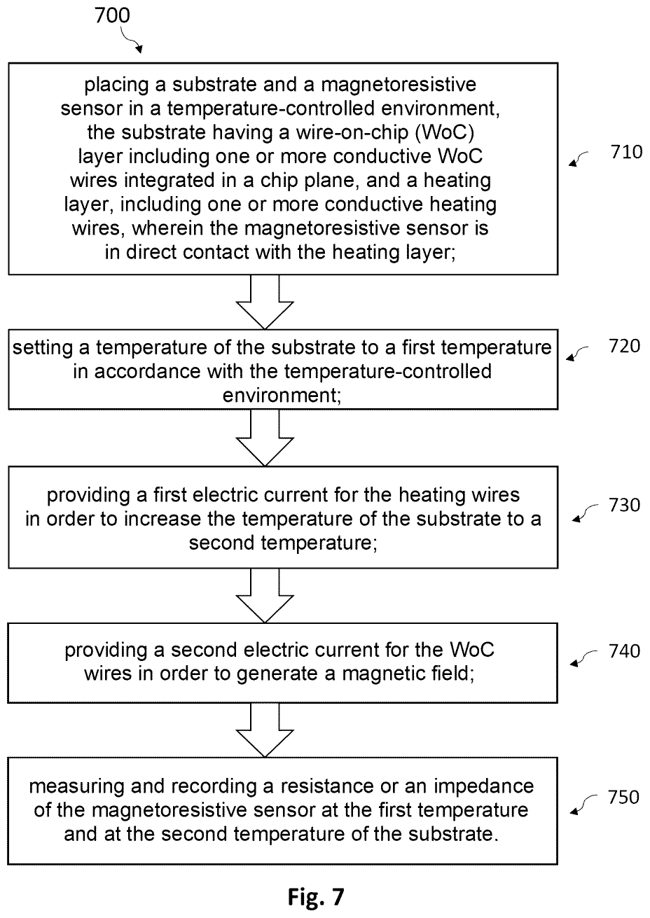

Hereinafter, a substrate for generating the predefined magnetic field and providing the temperature changes is presented with reference to FIG. 1. Further explanations in this regard are presented in FIGS. 2 to 6. The substrate may therefore be used for more efficient test methods, as illustrated in FIG. 7.

FIG. 1 schematically shows a first example of a substrate 100. The substrate 100 comprises a wire-on-chip layer, or WoC layer 110. The WoC layer 110 has one or more conductive WoC wires 112 integrated in a chip plane. Two WoC wires 112-1; 112-2 are illustrated by way of example in FIG. 1. The WoC wires 112-1; 112-2 are shown as being parallel to the plane of the drawing. The one or more WoC wires 112-1; 112-2 may be configured and positioned such that a specific magnetic field is generated at a predefined electric current and is able to be used to investigate an xMR sensor. The magnetic field may be based, inter alia, on a certain material and a certain diameter of the WoC wires 112-1; 112-2, which are dimensioned suitably.

The substrate 100 furthermore comprises a heating layer 120. The heating layer 120 has one or more conductive heating wires 122, which are represented here for example by two heating wires 122-1; 122-2. In principle, there may be any number of heating wires. The heating wires 122-1; 122-2 are illustrated such that they run perpendicular to the plane of the drawing. They are thus orthogonal to the WoC wires 112-1; 112-2 and the plane of the drawing. The one or more heating wires 122-1; 122-2 may be configured and positioned such that a predefined temperature increase (or change) of at least one section of the substrate, for example in close proximity to the heating wires 122-1; 122-2, is achieved at a predefined current. For this purpose, the one or more heating wires 122-1; 122-2 may have properties that are defined when the system is configured (for example diameter, material, etc.) in order to promote a high resistance and the generation of heat when an electric current is provided.

The substrate may be in direct contact with an xMR layer 130 (e.g., a sensor layer) comprising an xMR sensor 132, as illustrated. The xMR layer 130 may either be part of the substrate 100, by virtue of always being in direct contact, either thermal contact and/or physical contact (for example with thermal coupling and/or physical coupling) with the heating layer 120, or it may be constructed outside the substrate 100 and applied thereto. In the first case mentioned above, the substrate 100 may remain attached after the xMR sensor 132 has been tested (that is to say for the intended application as well), whereas, in the second case mentioned above, the substrate 100 may, as an alternative, also be separated from the xMR sensor after testing. The direct contact between the heating layer 120 and the xMR layer 130 may be established or made such that an increase in the temperature in the heating layer 120 also leads to a significant temperature increase in the xMR layer 130. By way of example, the heating wires 122-1; 122-2 may be placed in the upper half, closer to the xMR layer 130, in order to heat the xMR sensor 132 more effectively through conductive heating.

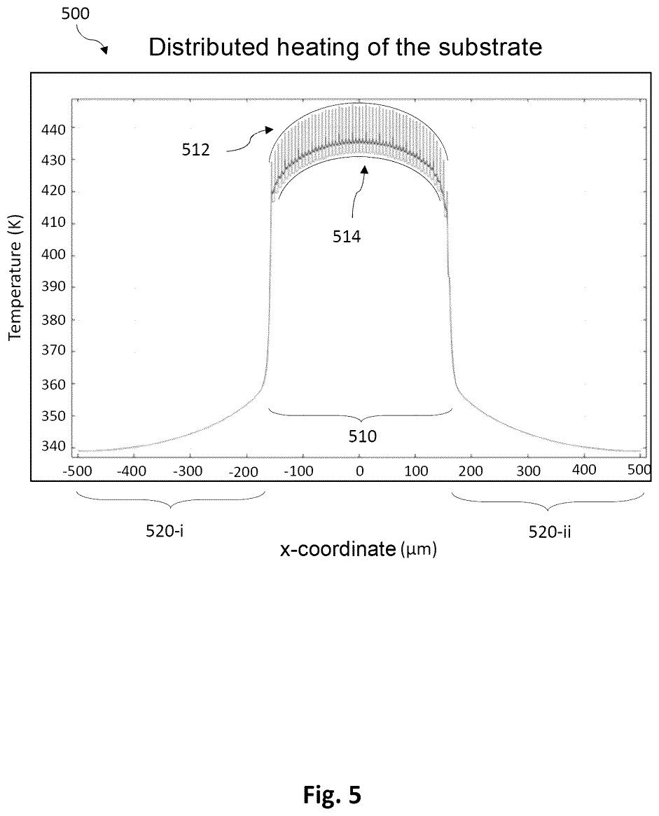

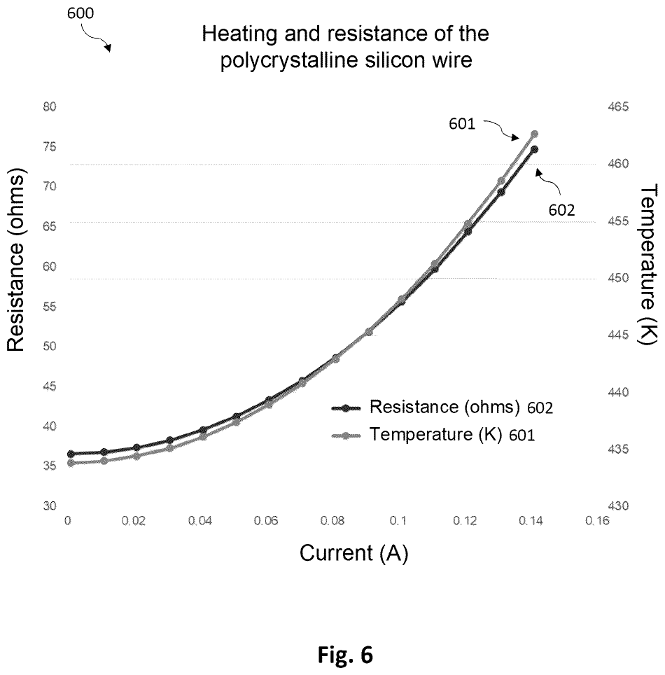

In order to ensure that the desired temperature is reached in the xMR sensor 132, the heating layer 120 (as shown) or xMR layer 130 may have a temperature sensor 129. Implementations having multiple temperature sensors are also possible. The temperature sensor may be configured such that it reproduces an accurate temperature measurement in accordance with a temperature change caused by the one or more heating wires 122-1; 122-2. The temperature sensor 129 may be in various forms. These may include, inter alia, silicon diode sensors, CMOS or MEMS temperature sensors, bandgap voltage reference sensors, thermal columns, resistance temperature detectors, and integrated infrared temperature sensors. By way of example, a respective temperature sensor 129 may be positioned at different locations of the heating layer 120 in order to measure a temperature change at the respective locations (as described in more detail for FIGS. 5 and 6).

The WoC wires 112-1; 112-2 may also be placed in the upper half of the WoC layer 110, closer to the xMR layer 130. This makes it possible to generate a stronger magnetic field for the same applied current around the xMR sensor. The WoC layer 110 and the heating layer 120 may be used to generate in each case different magnetic fields and large temperature changes in order to test the xMR sensor 132. The substrate 100 may thereby be suitable for different types of xMR sensors, as described in more detail for FIGS. 2A and 2B.

As described above, the xMR sensor 132 may be any type of magnetoresistive sensor that detects and measures magnetic fields with the aid of magnetoresistance. When an xMR sensor 132 is exposed to a magnetic field, there may be a change in electrical resistance due to a magnetoresistive effect. By way of example, one or more material layers in the xMR sensor may have a standard (or reference) electrical resistance (which may also vary due to other factors) when no external magnetic field is present, and may have a significantly changed electrical resistance when a sufficiently strong magnetic field is present.

The electrical resistance may change due to the GMR (giant magnetoresistance) effect, as briefly explained in FIG. 2A. An xMR sensor 132 may have multiple elements (that is to say units), such as the two illustrated elements 200-1; 200-2. Each element has at least one pinned (ferro-) magnetic layer 202-1; 202-2 each having a fixed magnetization direction, and at least one free (ferro-) magnetic layer 204-1; 204-2 each having a magnetization direction that is able to reorient itself depending on external magnetic fields. The pinned layer 202-1; 202-2 in both elements is oriented upwards, while the first free layer 204-1 in the first element 200-1 is oriented upwards and the second free layer 204-2 in the second element 200-2 is oriented downwards. There may be a non-magnetized material 206-1; 206-2 between the pinned layer and the free layer. Each layer may consist of a layer thickness of a few nanometers.

In the first element 200-1, both the pinned layer 202-1 and the free layer 204-1 are oriented in the same direction (upwards). For a predefined voltage, an electron may flow with less or more resistance, depending on a favorably or unfavorably oriented electron spin. With a favorably oriented spin, a flowing electron may experience less scattering (for example with either a downward spin 231 or an upward spin 232, as shown). In other words, if the free layer 204 and the pinned layer 200 are parallel relative to one another, there will be electrons that are able to flow with little resistance. This results in a higher current compared to the second element 200-2.

In the second element 200-2, the pinned layer 202-2 and the free layer 204-2 are oriented in opposite directions. For a predefined voltage, a higher resistance is caused, which will accordingly allow a smaller current to flow. The reason for this is that, regardless of the respective electron spin, all electrons in either the pinned layer or the free layer will be scattered to a considerable extent.

Generally speaking, a unit, such as the unit 200-1 or 200-2, may allow a significantly larger current to flow when the respective pinned layer and free layer are oriented parallel to one another. On the other hand, it allows a much smaller current to flow when the layers are oriented anti-parallel, with a gradual change between them.

The xMR sensor 132 may have multiple elements 200-1; 200-2 in order to detect and measure an external magnetic field, as shown in FIG. 2B. Four elements 261; 262; 263; 264 (illustrated in gray) are shown as one example of the xMR sensor 132 in the form of a Wheatstone measuring bridge. Two of the four elements (261; 264) are oriented in a first magnetization direction (to the right), while the other two elements (262; 263) are oriented in a second magnetization direction (anti-parallel to the first, to the left). A current may flow from a voltage input (Vcc) 240 to the ground point (GND) 242. Two voltage outputs 252; 254 may also provide a voltage measurement in order to measure a voltage drop across a respective resistance. If the resistance is able to be calculated for each element, this also makes it possible to determine the alignment of the magnetic field at each element. Other architectures are also possible.

Generally speaking, the xMR sensor 132 may be a GMR sensor (as explained above). It was explained in the previous example how the relative orientation of the magnetization directions may significantly change the electrical resistance through the layers. Other variants are also possible. In another example, the xMR sensor may be an AMR sensor based on an anisotropic magnetoresistive effect. In this case, the resistance change of the material when it is exposed to a magnetic field may occur along certain crystallographic axes. The angle between the current direction and the alignment of the light magnetization axis, as it is known, of the material may significantly influence the resistance.

In another example, the xMR sensor may be a TMR sensor based on a tunnel magnetoresistance quantum mechanical phenomenon. TMR sensors may also comprise two ferromagnetic layers (for example a pinned layer and a free layer), which are separated in particular by a thin insulating tunnel barrier. The relative alignment of magnetic moments may influence the tunneling and the resistance of electrons. TMR sensors may therefore be more suitable for highly sensitive applications for detecting small changes in magnetic fields.

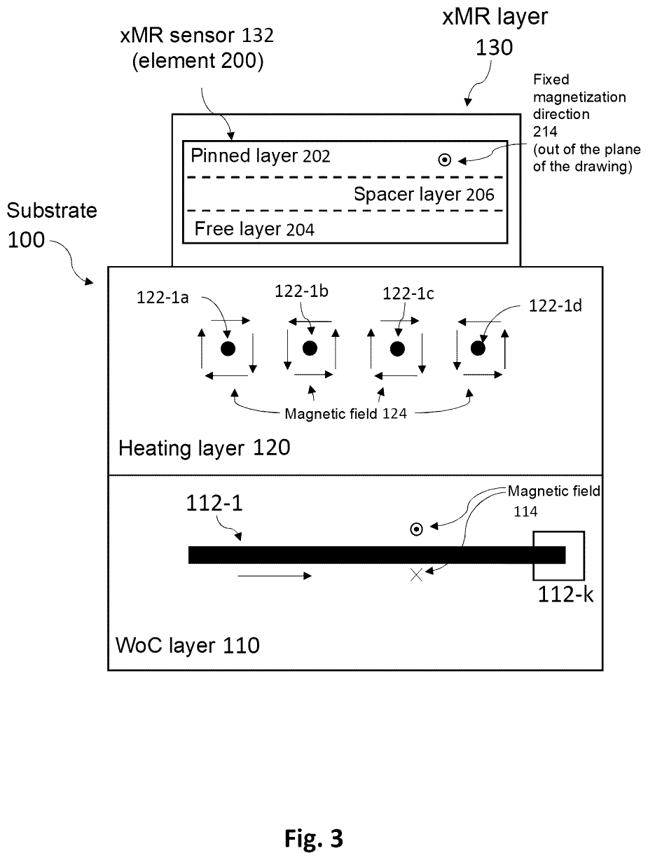

The examples from FIG. 2 allow a more precise explanation of the properties of the substrate 100 with reference to FIG. 3. The xMR layer 130 comprising an xMR sensor 132 is shown in direct contact with the heating layer 120 of the substrate 100. An arbitrary element 200 of the xMR sensor 132 is shown with a pinned layer 202, a free layer 204 and a spacer layer 206. The magnetization direction 214 of the element 200 is given as perpendicular to the plane of the drawing (out of the plane of the drawing).

FIG. 3 shows the magnetic fields accordingly of a WoC wire (magnetic field 114) and of a heating wire (magnetic field 124) in a simplified illustration. In the case of the magnetic fields (of the WoC wire 114 and of the pinned layer 202), a circle (o) represents an alignment of the magnetic field out of the plane of the drawing, while a cross (x) symbolizes an alignment of the magnetic field into the plane of the drawing. The WoC wires 112-1; 112-2 may be configured in the WoC layer 110 so as to influence the magnetization direction of the free layer 204 to a greater extent. On the other hand, the heating wires 122-1; 122-2 in the heating layer 120 may be configured so as to influence the magnetization direction of the free layer 204 to a lesser extent, as explained below.

The WoC wires 112-1; 112-2 may be configured so as to be orthogonal to the fixed magnetization direction 214 of the pinned layer 202, as shown for the WoC wire 112-1. When a predefined current is applied to the WoC wires, a predefined magnetic field will also be generated. The illustrated example shows an electric current to the right, which leads to a magnetic field that aligns out of the plane of the drawing (o) above the WoC wire 112-1 and aligns into the plane of the drawing (x) below the wire 112-1. The magnetic field above the WoC wire 112-1 is in the same direction as the magnetization direction 214 of the pinned layer (out of the plane of the drawing, o). In such a case, the free layer 204 (also positioned above the WoC wire 112-1) will also reorient itself due to this magnetic field parallel to the magnetization direction of the pinned layer 202, which will result in a significantly lower electrical resistance through the xMR element 200.

The opposite may likewise be achieved by providing an electric current in the opposite direction (to the left) in order to generate a magnetic field into the plane of the drawing (x) above the WoC wire 112-1 and out of the plane of the drawing (o) below the WoC wire 112-1. This causes the magnetization direction of the free layer 204 to align anti-parallel to the magnetization direction 214 of the pinned layer 202 due to this opposing magnetic field. This may cause significantly greater resistance through the xMR element 200.

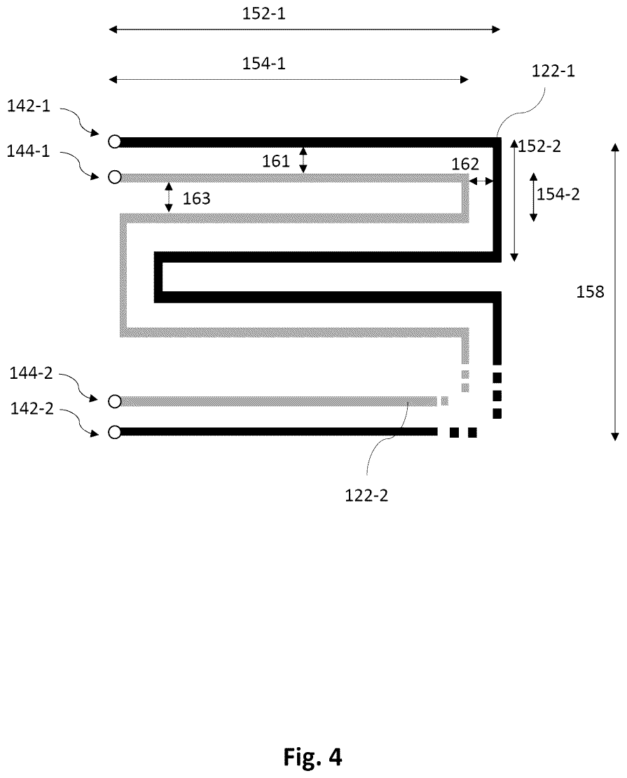

In order to ensure that the generated magnetic field of the WoC wire 112-1 remains as undisturbed as possible, the heating wires 122-1; 122-2 may be configured in a special way, for example so as to be meandering. The meandering shape and the advantages thereof are explained in more detail later in FIGS. 3 and 4. For simplified illustration, only one heating wire 122-1 with four sections 122-1a; 122-1b; 122-1c; 122-1d is shown. Two sections 122-1a; 122-1c are shown with the current flowing into the plane of the drawing, while the other two sections 122-1b; 122-1d are shown with the current flowing out of the plane of the drawing. The heating wire 122-1 generates a corresponding magnetic field 124.

Due to the different design of the sections 122-1a; 122-1b; 122-1c; 122-1d (orientation for the direction of an electric current), the respective portions of the magnetic field 124 are oriented in opposite directions. In a first example, the magnetic field 124 is oriented to the right above the first section 122-1a, while the magnetic field 124 is oriented to the left above the second, adjacent section 122-1b. Their effects may cancel one another out. The same applies in opposite directions of the magnetic field 124 below the sections 122-1a; 122-1b. In a second example, the magnetic field 124 is oriented upwards to the right of the second section 122-1b and to the left of the third section 122-c. On the other hand, the magnetic field 124 is oriented downwards to the right of the third section 122-1c and to the left of the fourth section 122-1d. This pattern is repeated, with the effects of multiple such pairs canceling one another out. The two examples serve to demonstrate that a meandering design of the heating wire 122-1 is able to minimize the effects of the generated magnetic field 124.

In the case of a meandering design of the heating wires 122-1; 122-2, the overall length cannot run parallel to the magnetization direction. At the least, it is necessary to introduce short sections for direction changes in order to keep the overall length within a compact range. In some implementations of the substrate 100, at least 75% of the length of the one or more heating wires 122-1; 122-2 is aligned parallel to the fixed magnetization direction. In other words, longer sections of the meandering design, which together make up more than 75% of the overall length, may all be aligned parallel to the fixed magnetization direction. Shorter sections, which together make up less than 25% of the overall length, may be aligned orthogonally.

The WoC wires 112-1; 112-2 may also be configured for example so as to be meandering. For this purpose, the WoC wires 112-1; 112-2 may also each have longer sections (like the section shown) that are able to generate a magnetic field 114 in either a parallel or anti-parallel direction to the fixed magnetization direction 214. Furthermore, the WoC wires may each have shorter sections (not shown), which are able to generate a magnetic field 114 in an orthogonal direction to the fixed magnetization direction 214.

In order to achieve a maximum effect on the magnetization direction of the free layer 204, the shorter sections of the one or more WoC wires 112-1; 112-2 that are aligned parallel to the fixed magnetization direction (and generate an orthogonal magnetic field) may be located outside a first predefined spacing from the free layer 204. On the other hand, the longer sections of the one or more WoC wires 112-1; 112-2 that are aligned orthogonally to the fixed magnetization direction (and generate a parallel or anti-parallel magnetic field) may be located within the abovementioned spacing from the free layer 204. One example of a shorter section of the WoC wire 112-1 that is aligned perpendicular to the plane of the drawing (shown in section 112-k) may be positioned outside the spacing, while the rest of the shown WoC wire 112-1 may be positioned within the spacing.

The same may apply analogously to the one or more heating wires 122-1; 122-2. In order to achieve a now minimum effect on the magnetization direction of the free layer 204, the sections of the one or more heating wires 122-1; 122-2 that are aligned orthogonally to the fixed magnetization direction 214 (and generate a parallel or anti-parallel magnetic field) may be located outside a second predefined spacing from the free layer 204. On the other hand, the sections of the one or more heating wires 122-1; 122-2 that are aligned parallel to the fixed magnetization direction 214 (and generate an orthogonal magnetic field) may be located within the abovementioned spacing from the free layer 204.

Additional specifications regarding the position and orientation of the heating wires 122-1; 122-2 may be specially selected to allow testing of the xMR sensor 132 over a wide range of different temperatures.

FIG. 4 schematically shows a meandering pattern of the conductive wires 122-1; 122-2 for one implementation of the heating layer 120. Two conductive wires 122-1; 122-2 are illustrated in black (122-1) and gray (122-2), each having a slightly adapted meandering pattern so as to allow multiple wires of a meandering pattern to be accommodated within a predefined region or volume. Each of the conductive wires comprises a corresponding first electrical contact 142-1; 144-1 and a respective second electrical contact 142-2; 144-2, by way of which an electric current is able to be provided.

A meandering pattern for a respective wire (heating wire 122-1; 122-2) may be thought of as sections of the wire that alternate between being long and short, with the alternating sections being aligned in orthogonal directions. By way of example, the wire may first be aligned in a straight line for a long section of the wire in a first direction (for example, left to right), followed by a straight line for a short section in a second direction orthogonal to the first direction (for example, top to bottom). This may then in turn be adjoined by a long section in the first direction (for example, left to right), with the current being able to flow in the opposite direction in order to keep the pattern within a compact range. Designs with curved direction changes are also possible. This pattern may be repeated multiple times in order to cover a significant region of the heating layer 120, for example large enough to bring about a significant temperature change for the entire xMR layer 130 or the entire xMR sensor 132.

Such a repetition is illustrated in the lower right-hand corner of FIG. 4 with dashed dots for both heating wires 122-1; 122-2. Above the lower right-hand corner, the first heating wire 122-1 (in black) is illustrated with a corresponding long section 152-1 and a short section 152-2. The second heating wire 122-2 (in gray) is likewise illustrated with a corresponding long section 154-1 and a short section 154-2.

The dashed sections (dots) of the heating wires 122-1; 122-2 represent a continuation of the meandering pattern of the long sections 152-1; 152-2 and of the short sections 154-1; 154-2 for any number of repetitions. In other words, the dashed sections may be repeated until the illustrated upper and lower sections of the heating wires 122-1; 122-2 are merged and span a certain width 158 of the heating layer 120. By virtue of an electric current being provided by way of the first electrical contacts 142-1; 144-1 and the second electrical contacts 142-2; 144-2, the resistance of the heating wires 122-1; 122-2 may lead to a uniformly distributed temperature increase.

Other features of such a configuration are likewise specified, including three examples of the spacing between the conductive heating wires 122-1; 122-2. A first spacing 161 is located between a long section of the first heating wire 122-1 and an adjacent parallel long section of the second heating wire 122-2, while a second spacing 162 is located between a short section of the first heating wire 122-1 and an adjacent parallel short section of the second heating wire 122-2. In addition, there is a third spacing 163 between two adjacent parallel long sections of the second heating wire 122-2. Each of the spacings 161; 162; 163 are illustrated as being roughly the same in FIG. 4.

The respective meandering patterns of the heating wires 122-1; 122-2 may be configured such that each of the spacings 161; 162; 163 between adjacent parallel heating wire sections, which may consist of the same or a different heating wire, is within a predefined maximum spacing. The maximum spacing may ensure a uniformly distributed temperature change if an electric current is provided for the heating wires 122-1; 122-2. By way of example, in some implementations, the predefined maximum spacing may, among other possibilities, be 5 μm. Larger maximum spacings may also enable an appropriate distribution of heat in the heating layer 120, depending on various factors (for example wire thickness).

The thickness of the respective heating wires 122-1; 122-2 may also be an important factor that allows a significant temperature change for a particular electric current. The thinner the heating wire 122-1; 122-2, the greater its resistance and the greater the corresponding temperature rise at a particular electric current. The thickness of the heating wires 122-1; 122-2 may be selected so as to remain at a minimum while at the same time maintaining a stable structure over a wide temperature range required to test the xMR sensor 132. In some implementations, the thickness of the respective heating wires 122-1; 122-2 is at most 2 μm so as to ensure a sufficient resistance and a corresponding temperature change. Other maximum thicknesses of the heating wires 122-1; 122-2 are also possible.

FIG. 5 shows a graph 500 graphically illustrating one example distribution of a temperature change of the heating layer 120. As described above, a previously defined electric current may lead to a previously defined temperature change for at least part of the substrate 100. By way of example, the temperature increase (or temperature change) for part of the substrate 100 may be greater than 50 K (kelvin) in order to allow a sufficient temperature range for testing the xMR sensor 132. Depending on the test requirements, the heating wires 122-1; 122-2 may be configured so as to achieve an even wider temperature range (for example a temperature increase of 110 K). Furthermore, in some implementations, the time scale of the temperature change based on the provided electric current is in the millisecond range.

In some implementations, a predefined electric current in the heating wires 122-1; 122-2 may cause a significant temperature change in a directly surrounding part of the substrate 100 (for example region 510), while it causes only an insignificant temperature change in more distant parts of the substrate 100 (for example regions 520-i; 520-ii). Such an implementation is illustrated in FIG. 5, in which a significant temperature change in the x-coordinate direction of the substrate is shown with reference to multiple measurement points. In the example of FIG. 5, the temperature of the substrate in a region of +160 μm around the center of the substrate (regions 510) is between approximately 418 K and 448 K. The increase corresponds approximately to a temperature change of 78 K to 108 K compared to a base temperature (340 K). On the other hand, the temperature increase drops rapidly outside this range (in the regions 520-i; 520-ii) and is significantly lower, such as at values of less than 360 K, or an increase of 20 K compared to the base temperature. Further outward, the temperature increase within a few micrometers further is less than 10 K, followed by a gradual drop-off over hundreds of micrometers.

A higher line 512 and a lower line 514 are each illustrated along the periodic peaks and valleys. In this example, each peak (local maximum) corresponds to a temperature of the heating wire 122-1; 122-2, while each valley (local minimum) corresponds to a temperature between two sections that are assigned to either the same heating wire or two different heating wires. It may be seen here that the temperature change between two such sections is not significantly lower compared to a section of the heating wire itself. Between the higher line 512 and the lower line 514, the temperature change is approximately 13 K. Furthermore, the closer to the center of the substrate (that is to say x=0 μm), the higher the temperature, up to 448 K. Closer to +160 μm, the temperature is lower, up to 418 K. By way of example, the xMR sensor 132 may be positioned within a range of +50 μm to ensure more efficient conduction of heat.

The temperature change may be measured using a temperature sensor, for example using an internal sensor such as the temperature sensor 129 from FIG. 1 or an external sensor. For the measurements corresponding to the peaks along the line 512, a temperature sensor may be in direct contact with the corresponding section of the heating wire 122-1; 122-2 (for example physical/thermal contact or with physical/thermal coupling, as described above). For the measurements corresponding to the valleys along the line 514, a temperature sensor may be in direct contact with a location of the substrate that lies exactly between two sections of a heating wire or two different heating wires. The thickness of the substrate (that is to say in the y-direction) may be within a few μm in order to effectively channel the heat from the one or more heating wires 122-1; 122-2 to the xMR layer 130, which is in direct contact with the heating layer 120.

The material of the heating layer 120 may be silicon, which may be selected due to its general suitability for the manufacture and integration of devices. Silicon may likewise have sufficient thermal conductivity, which makes it possible to increase the temperature of the surrounding volume around a heated heating wire 122-1; 122-2 when an electric current flows through the latter (due to its resistance). Other materials for the heating layer are also possible. In addition to the material of the heating layer 120, the material of the one or more heating wires 122-1; 122-2 may also optimize the temperature increase thereof, as illustrated in FIG. 6.

FIG. 6 shows a graph 600. The graph 600 provides a graphical illustration of one example of a temperature change 601 (with a scale on the right-hand y-axis) of a section of a conductive polycrystalline silicon wire. The temperature change depends on a provided electric current (with a scale on the x-axis) that flows through the polycrystalline silicon wire. The electric current varies between 0 and 0.14 amperes, resulting in a corresponding temperature of between 434 K and 463 K. In this example, the temperature change was measured by way of a resistance change 602 of a resistive temperature sensor integrated in a measuring device (with a scale on the left-hand y-axis). The resistance change of the temperature sensor corresponds to the temperature change of the section of the polycrystalline silicon wire, wherein the two lines 601; 602 for the temperature change and resistance change almost overlap.

In some implementations of the substrate 100, the one or more heating wires 122-1; 122-2 may be polycrystalline silicon wires. Polycrystalline silicon is a semiconductor material that is often used in integrated circuits and microelectronics. They have for example unique electrical, thermal and mechanical properties that make them suitable for special functions. Polycrystalline silicon is a material consisting of multiple small crystalline regions or silicon grains. Unlike monocrystalline silicon, which consists of a continuous and uniform crystal lattice structure, polysilicon consists of numerous individual crystal grains that are aligned in different directions.

The presence of grain boundaries in polysilicon makes it possible to reduce conductivity by inhibiting the movement of charge carriers (electrons and holes), resulting in a higher specific resistance of the material. At higher temperatures, like with other materials as well, charge carrier mobility generally decreases due to increased lattice vibrations and scattering mechanisms. The resistance change and the corresponding temperature change are thereby able to be increased at the same given electric current (compared to those for metal wires, for example). xMR sensors 132 to be tested, for example in direct contact with the heating layer 120, may then be tested in a larger temperature range. In addition, less current may be required to achieve the same temperature change.

FIGS. 1 to 6 present various features that may be integrated into the substrate 100 in order to enable more efficient testing of the functionality of the xMR sensor 132, including in a wide temperature range. Compared to testing the xMR sensor 132 with multiple test insertions, in which a probe needle has to be inserted at a precisely defined location, the substrate 100 disclosed herein may require just a single insertion. Temperature changes are able to be achieved in a stable manner, originating from the substrate 100 itself and leaving the test equipment undisturbed. The substrate 100 thus enables a new and more efficient form of testing, as illustrated in FIG. 7.

FIG. 7 shows a flowchart of a method 700 for investigating the functionality of xMR sensors (that is to say magnetoresistive sensors) at different temperatures. The method 700 comprises placing 710 a substrate and an xMR sensor in a temperature-controlled environment. The substrate has a wire-on-chip (WoC) layer, including one or more conductive WoC wires integrated in a chip plane. The substrate furthermore has a heating layer, including one or more conductive heating wires. The xMR sensor is in direct contact with the heating layer.

The method 700 furthermore comprises setting 720 a temperature of the substrate to a first temperature in accordance with the temperature-controlled environment. The method 700 furthermore comprises providing a first electric current 730 for the heating wires in order to increase the temperature of the substrate to a second temperature, and providing a second electric current 740 for the WoC wires in order to generate a magnetic field. The first electric current 730 may be passed through (e.g., caused to flow through, conducted by) the heating wires in order to generate heat corresponding to the amount of current. The second electric current 740 may be passed through (e.g., caused to flow through, conducted by) the WoC wires in order to generate a magnetic field corresponding to the amount of current. The method 700 furthermore comprises measuring and recording 750 a resistance or an impedance of the xMR sensor at the first temperature and at the second temperature of the substrate. The resistance or the impedance may be recorded by a processor into a memory component.

The method 700 may also comprise further steps. By way of example, the method 700 may furthermore include varying the first electric current for the heating wires in order to sequentially increase the temperature of the substrate, and, for a multiplicity of temperatures of the substrate, measuring and recording a resistance or an impedance of the xMR sensor corresponding to the respective temperature. In other words, the resistance or the impedance of the xMR sensor may be iteratively measured and recorded at each (different) temperature of the multiplicity of temperatures of the substrate. This makes it possible to ensure that the xMR sensor 132 is able to operate stably within a predefined temperature range at a large number of temperatures and with rapid temperature changes.

The method 700 may furthermore include, for the respective temperature, varying the second electric current for the WoC wires in order to generate a multiplicity of predefined magnetic fields, and, for each of the predefined magnetic fields, measuring and recording a resistance or an impedance of the xMR sensor corresponding to the respective magnetic field and the respective temperature. This makes it possible to ensure that the xMR sensor 132 is able to operate stably under different magnetic fields and at different temperatures. Both the magnetic fields and the temperatures are able to be changed quickly in order to ensure that the xMR sensor 132 responds quickly thereto and continuously measures the resistance of the xMR sensor precisely.

By way of example, it is possible to test more accurately whether the electrical resistance through each element of the xMR sensor changes, depending on the orientation of the free layer relative to the corresponding pinned layer. The resistance change is also able to be tested more accurately at different temperatures in order to ensure that the xMR sensor 132 is able to reliably detect and measure a surrounding magnetic field at different temperatures and that the accuracy and precision remain sufficiently high. Since a large number of xMR sensors have to be tested, the method 700 enables efficient testing of a multiplicity of xMR sensors under different magnetic fields and at different temperatures in less time, in particular compared to established test methods.

### ASPECTS

The aspects described here may be summarized as follows:
Aspect 1 is a substrate. The substrate comprises a wire-on-chip (WoC) layer, wherein the WoC layer has one or more conductive WoC wires for generating a magnetic field, the one or more conductive WoC wires being integrated in a chip plane. The substrate further comprises a heating layer, wherein the heating layer has one or more conductive heating wires for increasing a temperature of the substrate.
Aspect 2 is the substrate according to Aspect 1, wherein the heating layer is in thermal contact with the WoC layer.
Aspect 3 is the substrate according to Aspect 1 or Aspect 2, further having an xMR layer in direct contact with the heating layer, wherein the xMR layer has a magnetoresistive sensor, including a pinned layer having a fixed magnetization direction and a free layer having a magnetization direction corresponding to a surrounding magnetic field.
Aspect 4 is the substrate according to Aspect 3, wherein at least 75% of the length of the one or more heating wires is aligned parallel to the fixed magnetization direction and at least 75% of the length of the one or more WoC wires is aligned orthogonally to the fixed magnetization direction.
Aspect 5 is the substrate according to one of Aspects 1 to 4, wherein each section of the one or more heating wires that is aligned orthogonally to the fixed magnetization direction is located outside a first predefined spacing from the free layer, and wherein each section of the one or more WoC wires that is aligned parallel to the fixed magnetization direction is located outside a second predefined spacing from the free layer.
Aspect 6 is the substrate according to one of Aspects 1 to 5, wherein the one or more WoC wires are configured to generate a predefined magnetic field at a predefined current.
Aspect 7 is the substrate according to one of Aspects 1 to 6, wherein the heating layer has one or more heating wires in a meandering pattern, wherein each section of each of the one or more heating wires is aligned either in a first direction or in a second direction orthogonal to the first direction. Each heating wire of the one or more conductive heating wires has a meandering pattern, and wherein each section of each heating wire of the one or more conductive heating wires is aligned either in a first direction or in a second direction orthogonal to the first direction.
Aspect 8 is the substrate according to Aspect 7, wherein the one or more heating wires in the meandering pattern have a wire width of at most 2 μm and wherein the spacing between any two adjacent sections of the one or more heating wires aligned parallel to one another is within 5 μm.
Aspect 9 is the substrate according to one of Aspects 1 to 8, wherein the one or more heating wires are configured to cause a predefined temperature increase of at least one section of the substrate at a predefined current, wherein the temperature increase is above 50 K.
Aspect 10 is the substrate according to one of Aspects 1 to 9, wherein the one or more heating wires are polycrystalline silicon wires.
Aspect 11 is the substrate according to one of Aspects 1 to 10, wherein the heating layer has an integrated temperature sensor.
Aspect 12 is a method. The method comprises placing a substrate and a magnetoresistive sensor in a temperature-controlled environment, the substrate having a wire-on-chip (WoC) layer including one or more conductive WoC wires integrated in a chip plane, and a heating layer, including one or more conductive heating wires, wherein the magnetoresistive sensor is in direct contact with the heating layer. The method further comprises setting a temperature of the substrate to a first temperature in accordance with the temperature-controlled environment. The method further comprises providing a first electric current for the heating wires in order to increase the temperature of the substrate to a second temperature, and providing a second electric current for the WoC wires in order to generate a magnetic field. The method further comprises measuring and recording a resistance or an impedance of the magnetoresistive sensor at the first temperature and at the second temperature of the substrate.
Aspect 13 is the method according to Aspect 12, further including varying the first electric current for the heating wires in order to sequentially increase the temperature of the substrate, and, for a multiplicity of temperatures of the substrate, measuring and recording a resistance or an impedance of the magnetoresistive sensor corresponding to the respective temperature (e.g., for a multiplicity of temperatures of the substrate, measuring and recording the resistance or the impedance of the magnetoresistive sensor corresponding to each respective temperature of the multiplicity of temperatures).
Aspect 14 is the method according to Aspect 13, further including, for the respective temperature, varying the second electric current for the WoC wires in order to generate a multiplicity of predefined magnetic fields, and, for each of the predefined magnetic fields, measuring and recording a resistance or an impedance of the magnetoresistive sensor corresponding to the respective magnetic field and the respective temperature. For each respective temperature of the multiplicity of temperatures, varying the second electric current for the conductive WoC wires in order to generate a multiplicity of predefined magnetic fields, and, for each predefined magnetic field of the multiplicity predefined magnetic fields, measuring and recording the resistance or the impedance of the magnetoresistive sensor corresponding to the predefined magnetic field and the respective temperature.
Aspect 15: The substrate according to one of Aspects 1 to 10, wherein the one or more conductive heating wires include at least two conductive heating wires, and wherein the one or more conductive WoC wires include at least two conductive WoC wires.
Aspect 16: The substrate according to one of Aspects 1 to 10, wherein the one or more conductive heating wires include at least two conductive heating wires.
Aspect 17: The substrate according to one of Aspects 1 to 10, wherein the one or more conductive heating wires are configured to receive a first electric current in order to regulate the temperature of the substrate, and wherein the one or more conductive WoC wires are configured to receive a second electric current for generating a magnetic field.
Aspect 18: The substrate according to one of Aspects 1 to 10, wherein the one or more conductive heating wires are configured to receive a varying first electric current that is adjusted in order to sequentially increase the temperature of the substrate over a multiplicity of temperatures, and wherein for each respective temperature of a multiplicity of temperatures, the conductive WoC wires are configured to receive a varying second electric current that is adjusted in order to sequentially change a magnetic field generated by the conductive WoC wires over a multiplicity of predefined magnetic fields.
Aspect 19: A system configured to perform one or more operations recited in one or more of Aspects 1-18.
Aspect 20: An apparatus comprising means for performing one or more operations recited in one or more of Aspects 1-18.
Aspect 21: A non-transitory computer-readable medium storing a set of instructions, the set of instructions comprising one or more instructions that, when executed by a device, cause the device to perform one or more operations recited in one or more of Aspects 1-18.
Aspect 22: A computer program product comprising instructions or code for executing one or more operations recited in one or more of Aspects 1-18.

The aspects and features described in connection with a particular one of the previous aspects may also be combined with one or more of the other aspects to replace an identical or similar feature of this other aspect or to introduce the feature additionally into the other aspect.

Further, it goes without saying that the disclosure of multiple steps, processes, operations or functions disclosed in the description or claims should not be interpreted as necessarily being in the described order, unless this is explicitly stated in the individual case or is mandatory for technical reasons. Therefore, the previous description does not restrict the execution of multiple steps or functions to a specific order. Further, in other aspects, a single step, a single function, a single process or a single operation may include and/or be broken into multiple substeps, subfunctions, subprocesses or suboperations.

If some aspects have been described in the preceding sections in connection with a device or system, these aspects are also to be understood as a description of the corresponding method. In this case, for aspect, a block, a device or a functional aspect of the device or the system may correspond to a feature, such as a method step, of the corresponding method. Correspondingly, aspects described in connection with a method are also to be understood as a description of a corresponding block, a corresponding element, a property or a functional feature of a corresponding device or of a corresponding system.

The following claims are hereby incorporated into the detailed description, each claim being independent as a separate aspect. It should also be noted that—although a dependent claim in the claims refers to a particular combination with one or more other claims—other aspects may also comprise a combination of the dependent claim with the subject matter of any other dependent or independent claim. Such combinations are hereby explicitly proposed, unless it is stated in the individual case that a particular combination is not intended. Further, features of a claim should also be included for any other independent claim, even if that claim is not directly defined as dependent on that other independent claim.

1. A substrate, comprising:
a wire-on-chip (WoC) layer, wherein the WoC layer has one or more conductive WoC wires for generating a magnetic field, the one or more conductive WoC wires being integrated in a chip plane; and
a heating layer, wherein the heating layer has one or more conductive heating wires for increasing a temperature of the substrate.

2. The substrate as claimed in claim 1, wherein the heating layer is in thermal contact with the WoC layer.

3. The substrate as claimed in claim 1, further comprising an xMR layer in direct contact with the heating layer,
wherein the xMR layer includes a magnetoresistive sensor, including a pinned layer having a fixed magnetization direction and a free layer having a magnetization direction corresponding to a surrounding magnetic field.

4. The substrate as claimed in claim 3, wherein at least 75% of the length of the one or more conductive heating wires is aligned parallel to the fixed magnetization direction and at least 75% of the length of the one or more conductive WoC wires is aligned orthogonally to the fixed magnetization direction.

5. The substrate as claimed in claim 4,
wherein each section of the one or more conductive heating wires that is aligned orthogonally to the fixed magnetization direction is located outside a first predefined spacing from the free layer, and
wherein each section of the one or more conductive WoC wires that is aligned parallel to the fixed magnetization direction is located outside a second predefined spacing from the free layer.

6. The substrate as claimed in claim 1, wherein the one or more conductive WoC wires are configured to generate a predefined magnetic field at a predefined current.

7. The substrate as claimed in claim 1,
wherein each heating wire of the one or more conductive heating wires has a meandering pattern, and
wherein each section of each heating wire of the one or more conductive heating wires is aligned either in a first direction or in a second direction orthogonal to the first direction.

8. The substrate as claimed in claim 7,
wherein the one or more conductive heating wires have a wire width of at most 2 μm, and
wherein a spacing between any two adjacent sections of the one or more conductive heating wires aligned parallel to one another is within 5 μm.

9. The substrate as claimed in claim 1,
wherein the one or more conductive heating wires are configured to cause a predefined temperature increase of at least one section of the substrate at a predefined current, and
wherein the temperature increase is above 50 K.

10. The substrate as claimed in claim 1, wherein the one or more conductive heating wires are polycrystalline silicon wires.

11. The substrate as claimed in claim 1, wherein the heating layer includes an integrated temperature sensor.

12. A method, comprising:
placing a substrate and a magnetoresistive sensor in a temperature-controlled environment,
wherein the substrate comprises a wire-on-chip (WoC) layer that includes one or more conductive WoC wires integrated in a chip plane, and a heating layer, that includes one or more conductive heating wires,
wherein the magnetoresistive sensor is in direct contact with the heating layer;
setting a temperature of the substrate to a first temperature in accordance with the temperature-controlled environment;
providing a first electric current for the one or more conductive heating wires in order to increase the temperature of the substrate to a second temperature;
providing a second electric current for the one or more conductive WoC wires in order to generate a magnetic field; and
measuring and recording a resistance or an impedance of the magnetoresistive sensor at the first temperature and at the second temperature of the substrate.

13. The method as claimed in claim 12, further comprising:
varying the first electric current for the conductive heating wires in order to sequentially increase the temperature of the substrate, and
for a multiplicity of temperatures of the substrate, measuring and recording the resistance or the impedance of the magnetoresistive sensor corresponding to each respective temperature of the multiplicity of temperatures.

14. The method as claimed in claim 13, further comprising:
for each respective temperature of the multiplicity of temperatures, varying the second electric current for the conductive WoC wires in order to generate a multiplicity of predefined magnetic fields, and
for each predefined magnetic field of the multiplicity predefined magnetic fields, measuring and recording the resistance or the impedance of the magnetoresistive sensor corresponding to the predefined magnetic field and the respective temperature.

15. The substrate as claimed in claim 5, wherein the one or more conductive heating wires include at least two conductive heating wires, and
wherein the one or more conductive WoC wires include at least two conductive WoC wires.

16. The substrate as claimed in claim 8, wherein the one or more conductive heating wires include at least two conductive heating wires.

17. The substrate as claimed in claim 1, wherein the one or more conductive heating wires are configured to receive a first electric current in order to regulate the temperature of the substrate, and
wherein the one or more conductive WoC wires are configured to receive a second electric current for generating a magnetic field.

18. The substrate as claimed in claim 1, wherein the one or more conductive heating wires are configured to receive a varying first electric current that is adjusted in order to sequentially increase the temperature of the substrate over a multiplicity of temperatures, and
wherein for each respective temperature of a multiplicity of temperatures, the conductive WoC wires are configured to receive a varying second electric current that is adjusted in order to sequentially change a magnetic field generated by the conductive WoC wires over a multiplicity of predefined magnetic fields.
